(19) United States
(12) Patent Application Publication
(10) Pub. No.: US 2024/0337692 A1
(43) Pub. Date: Oct. 10, 2024

(54) Configurable Storage Circuits And Methods

(71) Applicant: Intel Corporation, Santa Clara, CA (US)

(72) Inventors: Rajiv Kumar, Tanjung Tokong (MY); Amit Agarwal, Hillsboro, OR (US); Steven Hsu, Lake Oswego, OR (US); Scott Weber, Piedmont, CA (US)

(73) Assignee: Intel Corporation, Santa Clara, CA (US)

(21) Appl. No.: 18/746,853

(22) Filed: Jun. 18, 2024

(51) Int. Cl. G01R 31/3185

(52) U.S. Cl. CPC G01R 31/318541; G01R 31/318572

(57) ABSTRACT

A flip-flop circuit includes first and second storage circuits. The flip-flop circuit is configurable to store first values of a data signal in the first storage circuit in response to rising edges of a clock signal and to store second values of the data signal in the second storage circuit in response to falling edges of the clock signal during a double edge triggered mode. The flip-flop circuit is configurable to store third values of the data signal in the first storage circuit and to output the third values from the first storage circuit in response to the clock signal during a single edge triggered mode.

### TECHNICAL FIELD

The present disclosure relates to electronic integrated circuits, and more particularly, to techniques for configurable storage circuits and methods.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate an image containing configuration data bits. The configuration data bits are then loaded into configuration memory elements that configure configurable logic circuits in the integrated circuit to perform the functions of the custom circuit design.

### BRIEF DESCRIPTION OF DRAWINGS

FIG. 1 is a diagram that depicts an example of a portion of an integrated circuit that includes programmable flip-flop circuits and conductors that are coupled to form a network-on-chip (NOC).

FIG. 2 is a diagram that depicts an example of a programmable flip-flop circuit.

FIG. 3 is a timing diagram that depicts examples of waveforms for signals in the programmable flip-flop circuit of FIG. 2.

FIG. 4 is a diagram that depicts another example of a programmable flip-flop circuit.

FIG. 5 is a diagram that depicts an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

In some types of configurable integrated circuits, the physical implementation of a fabric network-on-chip (NOC) uses dedicated data and control metal tracks over memory blocks to reduce fabric resources (e.g., routing and logic resources) and to achieve a high bandwidth and clock latency. However, a configurable integrated circuit may need to support many more signals than a standard size NOC can transmit. In addition, a NOC in a configurable integrated circuit may transport single data rate fabric configuration data using a single edge triggered (SET) flip-flop to save power. The SET flip-flop has no dependency on the clock duty cycle and a simplified interface to the NOC bus along with a single variant of the design. Also, the SET flip-flop may be scannable and compliant with a design-for-test methodology.

According to some examples disclosed herein, programmable flip-flop circuits are provided that can be configured in a double/dual edge triggered (DET) mode or in a single edge triggered (SET) mode. The programmable flip-flop circuits can also be configured in a scan mode and coupled to design-for-test (DFT) SET scan chains. The programmable flip-flop circuits can sample an input signal at both the rising and falling edges of an input clock signal in DET mode. In DET mode, the programmable flip-flop circuits can use half as many wires to transport the same amount of data compared to SET mode. The programmable flip-flop circuits only sample an input signal at edges of a clock signal that transition in one direction (e.g., only rising edges or only falling edges) in SET mode. The programmable flip-flop circuits can be used with double-data-rate applications, source synchronous busses, or any other applications that require a reduction in power consumption or a reduction in the number of physical wire tracks to reduce overall area. The programmable flip-flop circuits can provide efficient data movement for deep access into the programmable logic fabric of a configurable integrated circuit during DET mode. The programmable flip-flop circuits can be used for transmitting configuration data in SET mode or for DFT scan chains in scan mode. The programmable flip-flop circuits can also be used to transmit data using a clock signal that has duty cycle distortion in SET mode.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary components that allows the transfer of information between circuits. The term “circuit” may mean one or more passive and/or active electrical components that are arranged to cooperate with one another to provide a desired function.

This disclosure discusses integrated circuit (IC) devices, including configurable (programmable) logic integrated circuits, such as field programmable gate arrays (FPGAs) and programmable logic devices (PLDs). As discussed herein, an integrated circuit (IC) can include hard logic and/or soft logic. The circuits in an integrated circuit device (e.g., in a configurable logic IC) that are configurable by an end user are referred to as “soft logic.” “Hard logic” generally refers to circuits in an integrated circuit device that have substantially less configurable features than soft logic or no configurable features.

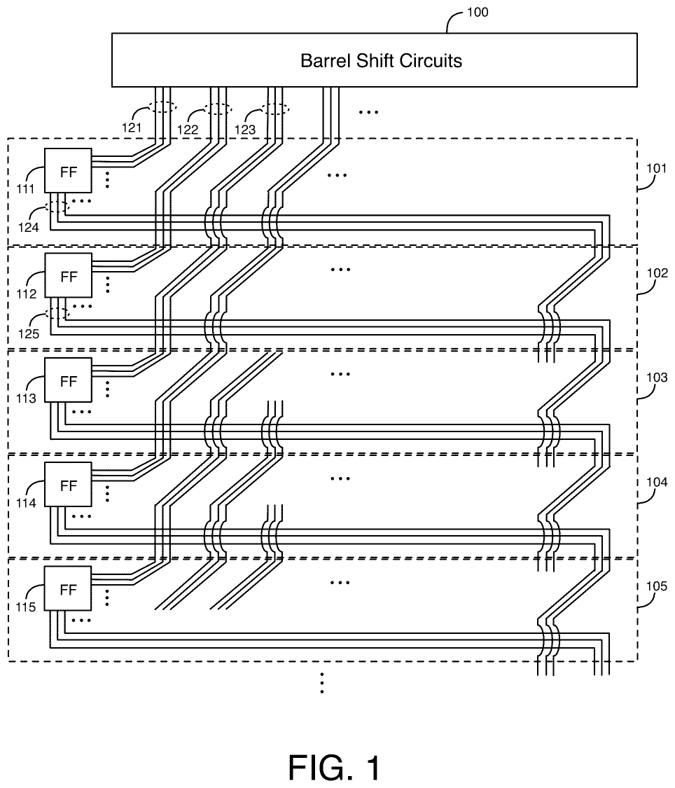

FIG. 1 is a diagram that depicts an example of a portion of an integrated circuit that includes programmable flip-flop circuits and conductors that are coupled to form a network-on-chip (NOC). Figure (FIG. 1 shows 5 regions 101-105 that include 5 of the programmable flip-flop circuits 111-115, respectively, as examples. According to various examples, an integrated circuit (IC) can have any number of programmable flip-flop circuits that have any of the architectures and any of the functionality disclosed herein. Each of the programmable flip-flop circuits, including the programmable flip-flop circuits 111-115 shown in FIG. 1, can be configured in a double/dual edge triggered (DET) mode, in a scan mode, or in a single edge triggered (SET) mode. The integrated circuit (IC) shown in FIG. 1 can be any type of IC, such as a configurable IC (e.g., an FPGA), a microprocessor IC, a graphics processing unit (GPU) IC, a memory IC, an application specific IC, etc. The programmable flip-flop circuits disclosed herein are also referred to as configurable or programmable storage circuits.

The IC shown in FIG. 1 also includes barrel shift circuits 100 and conductors (i.e., conductive wires) that are coupled to form a network-on-chip (NOC). The conductors that form the NOC include conductors 121, 122, 123, 124, and 125. The programmable flip-flop circuits 111, 112, and 113 are coupled to the barrel shift circuits 100 through conductors 121, 122, and 123, respectively. The programmable flip-flop circuits 111-115 etc. are coupled to other ones of the programmable flip-flop circuits in the IC through conductors in the NOC (e.g., conductors 124-125). For example, the programmable flip-flop circuit 111 in region 101 can be coupled to programmable flip-flop circuit 115 in region 105, or another programmable flip-flop circuit in the IC (e.g., the eighth programmable flip-flop circuit in the IC) through conductors 124.

The IC of FIG. 1 can have a 50% reduction in the number of conductors (wires) in the NOC to transmit the same amount of data by operating the programmable flip-flop circuits 111-115 etc. in the DET mode and achieve functionality and bandwidth according to user specifications. The functionality provided in DET mode can be achieved with lower power using the programmable flip-flop circuits. The programmable flip-flop circuits are capable of capturing data at twice the data rate in DET mode compared to SET mode, in response to a clock signal having the same clock frequency in both the DET and SET modes. Operating the programmable flip-flop circuits in the DET mode can provide a clock power saving by using a clock frequency that is half the double data rate in DET mode. Thus, the configuration of FIG. 1 can reduce the clock distribution power consumption in DET mode.

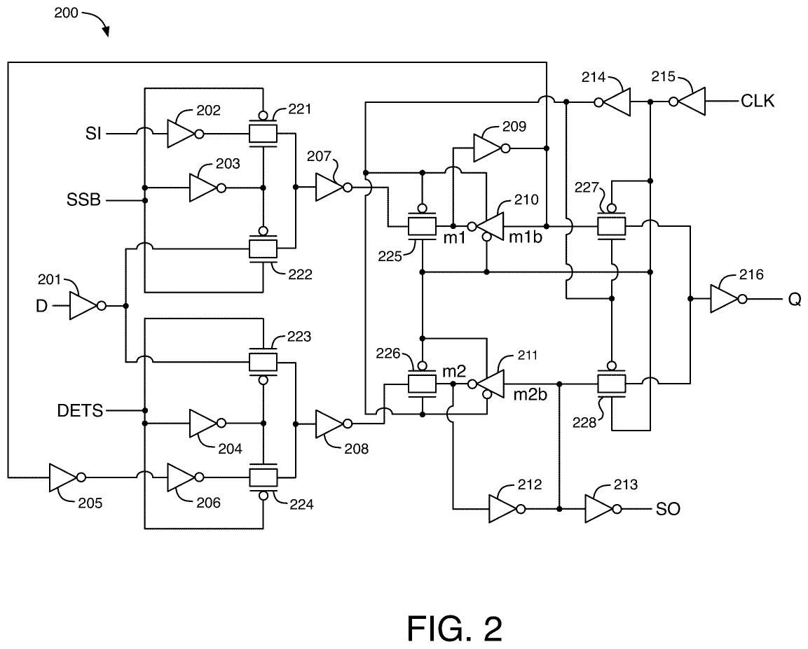

FIG. 2 is a diagram that depicts an example of a programmable flip-flop circuit 200. As examples, the programmable flip-flop circuit 200 of FIG. 2 can be used as any one or more of the programmable flip-flop circuits 111-115 in the IC shown in FIG. 1. The programmable flip-flop circuit 200 of FIG. 2 can be configured in a double/dual edge triggered (DET) mode, in a scan mode, or in a single edge triggered (SET) mode. The programmable flip-flop circuit 200 can sample an input signal D at both the rising and falling edges of an input clock signal CLK in DET mode. In SET mode, the programmable flip-flop circuit 200 only samples the input signal D at edges of input clock signal CLK that transition in one direction (e.g., only rising edges or only falling edges).

In DET mode, the programmable flip-flop circuit 200 can use half as many wires to transmit the same amount of data from signal D compared to the SET mode. The programmable flip-flop circuit 200 can store and transmit data at twice the data rate in DET mode compared to SET mode. The programmable flip-flop circuit 200 can also reduce clock power consumption. The programmable flip-flop circuit 200 can also be coupled to design-for-test (DFT) SET scan chains and operated in a scan mode.

The programmable flip-flop circuit 200 of FIG. 2 includes 16 inverter circuits 201-216 and 8 pass gate circuits 221-228. Each of the inverter circuits 201-216 can be, for example, a complementary metal oxide semiconductor (CMOS) inverter circuit. Each of the pass gate circuits 221-228 includes a p-channel field-effect transistor (FET) coupled in parallel with an n-channel field-effect transistor (FET), as shown in FIG. 2. According to other examples, any suitable combination of devices can be used to implement the pass gate and inverter functions in the programmable flip-flop circuit 200. For example, a pass gate and an inverter function can be achieved using a tri-state inverter circuit.

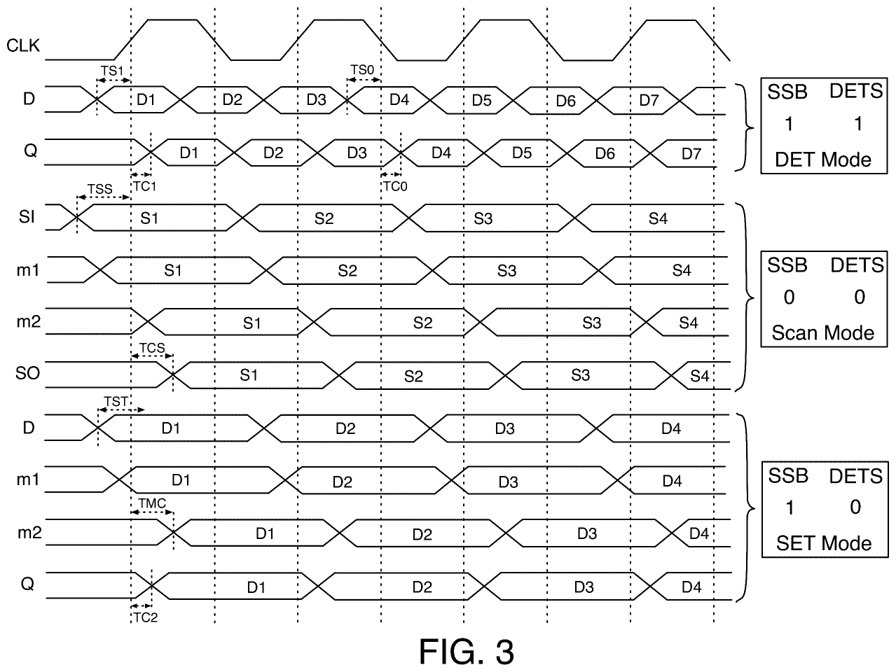

FIG. 3 is a timing diagram that depicts examples of waveforms for signals in the programmable flip-flop circuit 200 of FIG. 2. FIG. 3 shows an example of a waveform for the clock signal CLK provided to the input of inverter circuit 215 in programmable flip-flop circuit 200. FIG. 3 shows examples of waveforms for the input data signal D and the output signal Q of programmable flip-flop circuit 200 during the DET mode. The input data signal D is provided to the input of inverter circuit 201, and output signal Q is generated at the output of inverter circuit 216. In addition, FIG. 3 shows examples of waveforms for signals SI, m1, m2, and SO during the scan mode of programmable flip-flop circuit 200. Signal SI is a scan in input signal provided to the input of inverter circuit 202, and signal SO is a scan out signal generated at the output of inverter circuit 213. Signal m1 is generated by inverter circuit 207 or 210, and signal m2 is generated by inverter circuit 208 or 211, as shown in FIG. 2. Also, FIG. 3 shows examples of waveforms for signals D, m1, m2, and Q during the SET mode of programmable flip-flop circuit 200.

A detailed example of the operation of the DET mode of the programmable flip-flop circuit 200 of FIG. 2 is now described with respect to the waveforms for signals D and Q shown in the upper portion of FIG. 3. In the DET mode, signals SSB and DETS are asserted to logic high states (i.e., digital 1 states), as shown in FIG. 3. Signal SSB is an input signal that is provided to the input of inverter circuit 203, to the gate of the p-channel FET in pass gate circuit 221, and to the gate of the n-channel FET in pass gate circuit 222. The output of inverter circuit 203 is coupled to the gate of the p-channel FET in pass gate circuit 222 and to the gate of the n-channel FET in pass gate circuit 221. When signal SSB is 1 in DET mode, pass gate circuit 221 is off, and pass gate circuit 222 is on. When pass gate circuit 221 is off, the inverter 202 that receives scan in signal SI is decoupled from the input of inverter circuit 207. As a result, during DET mode, the scan path generating signal SI is decoupled from the output of the programmable flip-flop circuit 200 at signal Q. When pass gate circuit 222 is on, pass gate circuit 222 couples the output of inverter circuit 201 to the input of inverter circuit 207.

Signal DETS is an input signal that is provided to the input of inverter circuit 204, to the gate of the n-channel FET in pass gate circuit 223, and to the gate of the p-channel FET in pass gate circuit 224. The output of inverter circuit 204 is coupled to the gate of the p-channel FET in pass gate circuit 223 and to the gate of the n-channel FET in pass gate circuit 224. When signal DETS is 1 in DET mode, pass gate circuit 223 is on, and pass gate circuit 224 is off. When pass gate circuit 224 is off, the output of inverter circuit 206 is decoupled from the input of inverter circuit 208. When pass gate circuit 223 is on, pass gate circuit 223 couples the output of inverter circuit 201 to the input of inverter circuit 208. Thus, during DET mode, the data input path that generates signal D is coupled to the inputs of inverter circuits 207-208.

The programmable flip-flop circuit 200 includes two latch storage circuits that are used to store the values of the input data signal D during the DET mode. The first latch storage circuit includes two cross-coupled inverter circuits 209 and 210 that are coupled between pass gate circuits 225 and 227. The second latch storage circuit includes two cross-coupled inverter circuits 211 and 212 that are coupled between pass gate circuits 226 and 228.

Inverter circuits 210 and 211 are tri-state inverter circuits each having two control inputs that are controlled by clock signal CLK. In programmable flip-flop circuit 200, clock signal CLK is provided through inverter circuit 215 to the inverting control input of tri-state inverter circuit 210, to the non-inverting control input of tri-state inverter circuit 211, to the p-channel FET in pass gate circuit 227, to the n-channel FET in pass gate circuit 228, to the n-channel FET in pass gate circuit 225, and to the p-channel FET in pass gate circuit 226. Also, clock signal CLK is provided through inverter circuits 215 and 214 to the non-inverting control input of tri-state inverter circuit 210, to the inverting control input of tri-state inverter circuit 211, to the n-channel FET in pass gate circuit 227, to the p-channel FET in pass gate circuit 228, to the p-channel FET in pass gate circuit 225, and to the n-channel FET in pass gate circuit 226.

When the clock signal CLK is low (i.e., in a logic low state), the pass gate circuits 225 and 228 are on, the pass gate circuits 226-227 are off, inverter circuit 210 is tri-stated off, and inverter circuit 211 is on. As a result, when CLK is low in DET mode, the data signal D is provided through inverter circuit 201, through pass gate circuit 222, through inverter circuit 207, through pass gate circuit 225, and through inverter circuit 209 to the input of inverter circuit 210 (as signal m1b) in the first latch storage circuit that includes inverter circuits 209-210.

In response to the next rising edge of clock signal CLK in DET mode, pass gate circuits 225 and 228 turn off, pass gate circuits 226-227 turn on, inverter circuit 210 turns on, and inverter circuit 211 is tri-stated off. When inverter circuit 210 turns on, the value of the data signal D is stored in the first latch storage circuit at the output of inverter circuit 210 (as signal m1). When pass gate 227 turns on, the value of the data signal D is provided to the output signal Q at an output of programmable flip-flop circuit 200 from signal m1b through pass gate circuit 227 and through inverter circuit 216. Thus, the first latch storage circuit stores the value of the data signal D and provides the value of data signal D to signal Q. FIG. 3 also shows examples of the setup time TS1 for the first latch storage circuit to store the value of signal D before each rising edge of clock signal CLK and the time TC1 after each rising edge of clock signal CLK for the value of the data signal D to appear in signal Q. As examples, values D1, D3, D5, and D7 of data signal D shown in FIG. 3 are provided to signal Q after each respective rising edge in clock signal CLK.

When the clock signal CLK is high (i.e., in a logic high state), the pass gate circuits 225 and 228 are off, the pass gate circuits 226-227 are on, inverter 210 is on, and inverter 211 is tri-stated off. As a result, when CLK is high in DET mode, the data signal D is provided through inverter circuit 201, through pass gate circuit 223, through inverter circuit 208, through pass gate circuit 226, and through inverter circuit 212 to the input of inverter circuit 211 (as signal m2b) in the second latch storage circuit that includes inverter circuits 211-212.

Then, in response to the next falling edge of clock signal CLK in DET mode, pass gate circuits 225 and 228 turn on, pass gate circuits 226-227 turn off, inverter 210 is tri-stated off, and inverter 211 turns on. When inverter circuit 211 turns on, the value of the data signal D is stored in the second latch storage circuit at the output of inverter circuit 211 (as signal m2). When pass gate circuit 228 turns on, the value of the data signal D is provided to the output signal Q at the output of programmable flip-flop circuit 200 from signal m2b through pass gate circuit 228 and through inverter circuit 216. Thus, the second latch storage circuit stores the value of data signal D and provides the value of data signal D to signal Q. FIG. 3 shows examples of the setup time TS0 for the second latch storage circuit to store the value of signal D before each falling edge of clock signal CLK and the time TC0 after each falling edge of clock signal CLK for the value of data signal D to appear in signal Q. As examples, values D2, D4, and D6 of data signal D shown in FIG. 3 are provided to signal Q after each respective falling edge in clock signal CLK.

A detailed example of the operation of the scan mode of the programmable flip-flop circuit 200 of FIG. 2 is now described with respect to the waveforms for signals SI, m1, m2, and SO shown in the middle portion of FIG. 3. In the scan mode, signals SSB and DETS are asserted to logic low states (i.e., digital 0 states), as shown in FIG. 3. When signal SSB is 0 in scan mode, pass gate circuit 221 is on, and pass gate circuit 222 is off. When pass gate circuit 222 is off, the output of inverter circuit 201 is decoupled from the input of inverter circuit 207. Thus, during scan mode, the data input path generating signal D is decoupled from inverter circuit 207 and from the output of the programmable flip-flop circuit 200 at signal Q. When pass gate circuit 221 is on, the pass gate circuit 221 couples the scan in path that provides scan in signal SI to the input of inverter circuit 207.

When signal DETS is 0 in scan mode, pass gate circuit 223 is off, and pass gate circuit 224 is on. When pass gate circuit 223 is off, the output of inverter circuit 201 is decoupled from the input of inverter circuit 208. Thus, during scan mode, the data input path generating signal D is decoupled from inverter circuit 208 and from the output of the programmable flip-flop circuit 200 at signal Q. When pass gate circuit 224 is on, pass gate circuit 224 couples the output of inverter circuit 206 to the input of inverter circuit 208. As a result, signal m1b is provided through inverter circuits 205-206 and through pass gate circuit 224 to the input of inverter circuit 208.

When clock signal CLK is low in scan mode, the scan in signal SI is provided through inverter circuit 202, through pass gate circuit 221, through inverter circuit 207, through pass gate circuit 225 to signal m1, and through inverter circuit 209 to the input of inverter circuit 210 (as signal m1b) in the first latch storage circuit that includes inverter circuits 209-210. In response to the next rising edge of clock signal CLK in scan mode, pass gate circuits 225 and 228 turn off, pass gate circuits 226-227 turn on, inverter circuit 210 turns on, and inverter circuit 211 is tri-stated off. When inverter circuit 210 turns on, the value of the signal SI is stored in the first latch storage circuit at the output of inverter circuit 210 (as signal m1).

When clock signal CLK is high in scan mode, signal m1b is provided through inverter circuits 205-206, through pass gate circuit 224, through inverter circuit 208, through pass gate circuit 226 to signal m2, through inverter circuit 212 to the input of inverter circuit 211 (to signal m2b), and through inverter circuit 213 to the scan out signal SO at a scan output of programmable flip-flop circuit 200. FIG. 3 shows an example of the scan setup time TSS for the value of signal SI to appear in signal m2. TSS is greater than TS1 and TS0. As examples, values S1-S4 of signal SI shown in FIG. 3 are stored as signals m1 and m2.

Then, in response to the next falling edge of clock signal CLK in scan mode, pass gate circuits 225 and 228 turn on, pass gate circuits 226-227 turn off, inverter 210 is tri-stated off, and inverter 211 turns on. When inverter circuit 211 turns on, the inverted value of signal m2b is stored in the second latch storage circuit at the output of inverter circuit 211 as signal m2. Thus, the programmable flip-flop circuit 200 stores the value of the scan in signal SI and provides the stored value (i.e., logic state) of scan in signal SI to the scan out signal SO. FIG. 3 shows an example of the time TCS after a rising edge of clock signal CLK for the value of signal SI to be transmitted to signal SO. TCS is greater than each of times TC1 and TC0. As examples, values S1-S4 of signal SI shown in FIG. 3 are provided to signal SO after each respective rising edge in clock signal CLK.

A detailed example of the operation of the SET mode of the programmable flip-flop circuit 200 of FIG. 2 is now described with respect to the waveforms for signals D, m1, m2, and Q shown in the lower portion of FIG. 3. In the SET mode, signal SSB is asserted to a logic high state (1), and signal DETS is asserted to a logic low state (0), as shown in FIG. 3. When signal SSB is 1 in SET mode, pass gate circuit 221 is off, pass gate circuit 222 is on, and the scan in path generating signal SI is decoupled from the input of inverter circuit 207. When signal DETS is 0 in SET mode, pass gate circuit 223 is off, pass gate circuit 224 is on, and the output of inverter circuit 201 is decoupled from the input of inverter circuit 208. During SET mode, the data input path that generates signal D is coupled to the input of inverter circuit 207 and decoupled from the input of inverter circuit 208.

When CLK is low in SET mode, the value of data signal D is provided through inverter circuit 201, through pass gate circuit 222, through inverter circuit 207, through pass gate circuit 225 (to signal m1), and through inverter circuit 209 to the input of inverter circuit 210 (to signal m1b) in the first latch storage circuit. In response to the next rising edge of clock signal CLK in SET mode, inverter circuit 210 turns on, and the value of data signal D is stored in the first latch storage circuit at the output of inverter circuit 210 (as signal m1). Also, pass gate circuit 227 turns on at the rising edge of CLK, and the value of the data signal D stored in the first latch storage circuit is provided through pass gate circuit 227 and through inverter circuit 216 to the output signal Q at the output of programmable flip-flop circuit 200. The first latch storage circuit stores the value of the data signal D and provides the value of data signal D to signal Q after each rising edge of clock signal CLK in SET mode.

FIG. 3 shows examples of the setup time TST for the first latch storage circuit to store the value of signal D before each rising edge of clock signal CLK, the time TMC for the value of signal m1 to propagate to signal m2, and the time TC2 after each rising edge of clock signal CLK for the value of data signal D to propagate from signal m1b to signal Q. As examples, values D1-D4 of data signal D shown in FIG. 3 are provided to signal Q after each respective rising edge in clock signal CLK. In SET mode, the data rate of signal Q equals the data rate of signal D. The data rates of signals D and Q in DET mode can be two times the data rates of signals D and Q in SET mode, respectively.

Also, when clock signal CLK is high in SET mode, signal m1b is provided through inverter circuits 205-206, through pass gate circuit 224, through inverter circuit 208, through pass gate circuit 226 to signal m2, and through inverter circuit 212 to the input of inverter circuit 211 (to signal m2b) in the second latch storage circuit. The second latch storage circuit that includes inverter circuits 211-212 then stores the value of the data signal D in signal m2 when the clock signal CLK is low. Also, when clock signal CLK is low, the value of the data signal D stored in the second latch storage circuit in signal m2 is provided through inverter circuit 212, through pass gate circuit 228, and through inverter circuit 216 to output signal Q. The value of output signal Q remains the same in SET mode until a new value of signal D propagates to signal Q through the first latch storage circuit and pass gate circuit 227.

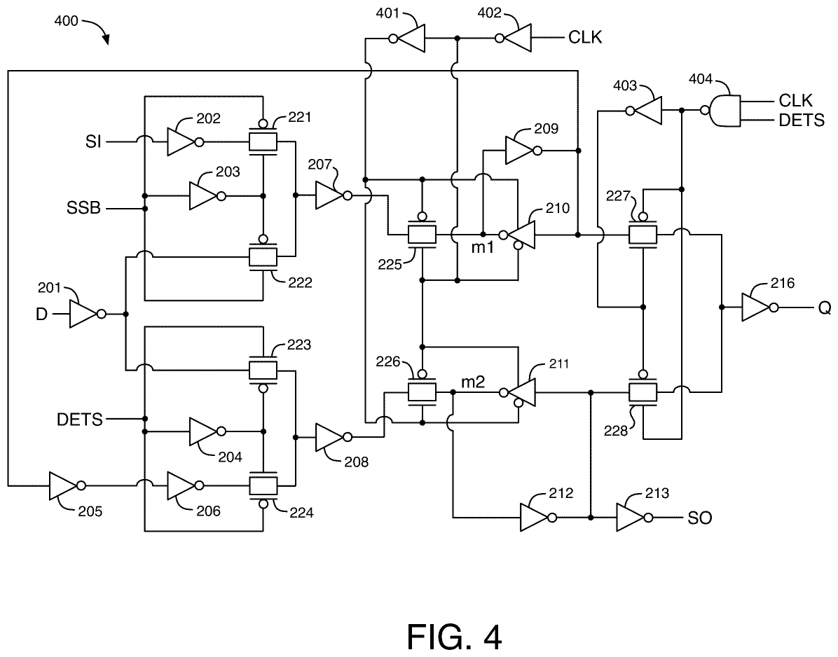

FIG. 4 is a diagram that depicts another example of a programmable flip-flop circuit 400. As examples, the programmable flip-flop circuit 400 of FIG. 4 can be used as any one or more of the programmable flip-flop circuits 111-115 in the IC shown in FIG. 1. The programmable flip-flop circuit 400 of FIG. 4 can be configured in a double/dual edge triggered (DET) mode, in a single edge triggered (SET) mode, or in a scan mode. The programmable flip-flop circuit 400 can sample an input data signal D at both the rising and falling edges of the input clock signal CLK in DET mode. In SET mode, the programmable flip-flop circuit 400 only samples input data signal D at edges of input clock signal CLK that transition in one direction (e.g., only rising edges or only falling edges). In DET mode, programmable flip-flop circuit 400 can use half as many wires as in the SET mode to store and transmit the same amount of data in signal D. The programmable flip-flop circuit 400 can also reduce clock power consumption. The programmable flip-flop circuit 400 can store and transmit data at twice the data rate in DET mode compared to SET mode.

The programmable flip-flop circuit 400 of FIG. 4 includes 8 pass gate circuits 221-228, a NAND logic gate circuit 404, and 16 inverter circuits 201-213 and 401-403. The 8 pass gate circuits 221-228 and the inverter circuits 201-213 of programmable flip-flop circuit 400 are coupled together in the same configuration as in the programmable flip-flop circuit 200. However, in programmable flip-flop circuit 400, clock signal CLK is provided through inverter circuit 402 to the inverting control input of tri-state inverter circuit 210, to the non-inverting control input of tri-state inverter circuit 211, to the n-channel FET in pass gate circuit 225, and to the p-channel FET in pass gate circuit 226. Also, clock signal CLK is provided through inverter circuits 402 and 401 to the non-inverting control input of tri-state inverter circuit 210, to the inverting control input of tri-state inverter circuit 211, to the p-channel FET in pass gate circuit 225, and to the n-channel FET in pass gate circuit 226.

The clock signal CLK and signal DETS are provided to inputs of NAND logic gate circuit 404, which performs a NAND Boolean logic function on signals CLK and DETS to generate the value of its output signal. The output signal of NAND logic gate circuit 404 is provided to the p-channel FET in pass gate circuit 227, to the n-channel FET in pass gate circuit 228, and to the input of inverter circuit 403. The output signal of inverter circuit 403 is provided to the n-channel FET in pass gate circuit 227 and to the p-channel FET in pass gate circuit 228.

The waveforms shown in FIG. 3 are also valid examples for illustrating the DET mode and the scan mode of programmable flip-flop circuit 400. In the DET mode of programmable flip-flop circuit 400, the signals SSB and DETS are asserted to logic high states (1), as shown in FIG. 3. During the DET mode of programmable flip-flop circuit 400, pass gate circuit 221 is off decoupling the scan path generating signal SI from inverter circuit 207, and pass gate circuit 222 couples the output of inverter circuit 201 to the input of inverter circuit 207. Also, during the DET mode, pass gate circuit 224 is off decoupling the output of inverter circuit 206 from the input of inverter circuit 208, and pass gate circuit 223 is on coupling the output of inverter circuit 201 to the input of inverter circuit 208. Thus, during DET mode, the data input path that generates signal D is coupled to the inputs of inverter circuits 207-208.

Also, because signal DETS is 1 in DET mode, NAND gate circuit 404 functions as an inverter circuit, and all of the oscillations in clock signal CLK propagate through NAND gate circuit 404 and inverter circuit 403 to the pass gate circuits 227-228. As a result, the programmable flip-flop circuit 400 functions in DET mode as described above with respect to FIGS. 2 and 3 for the programmable flip-flop circuit 200 in DET mode. Thus, the value of the data signal D propagates from the first latch storage circuit comprising inverter circuits 209-210 to signal Q after each rising edge of the clock signal CLK, and the value of data signal D propagates from the second latch storage circuit comprising inverter circuits 211-212 to signal Q after each falling edge of the clock signal CLK.

During the scan mode of programmable flip-flop circuit 400, scan in signal SI is provided to the input of inverter circuit 202, and scan out signal SO is generated at the output of inverter circuit 213. In the scan mode, signals SSB and DETS are asserted to logic low states (0), as shown in FIG. 3. As a result, pass gate circuit 222 is off decoupling the data input path and inverter circuit 201 from inverter circuit 207, and pass gate circuit 221 is on coupling the scan in path that provides signal SI to the input of inverter circuit 207. In addition, pass gate circuit 223 is off decoupling the data input path and inverter circuit 201 from inverter circuit 208, and pass gate circuit 224 is on coupling the output of inverter circuit 206 to the input of inverter circuit 208. Also, because signal DETS is 0 in scan mode, NAND gate circuit 404 continuously generates a logic high state (1) at its output, causing pass gate circuit 227 to remain off and pass gate circuit 228 to remain on.

The programmable flip-flop circuit 400 functions in scan mode as described above with respect to FIGS. 2 and 3 for the programmable flip-flop circuit 200 in the scan mode. Thus, the value of the scan in signal SI is provided through inverter circuit 202, pass gate circuit 221, inverter circuit 207, and pass gate circuit 225 to the first latch storage circuit and then stored in the first latch storage circuit. Subsequently, the value of signal SI stored in the first latch storage circuit is provided to the second latch storage circuit (through inverter circuits 205-206, pass gate circuit 224, inverter circuit 208, and pass gate circuit 226), stored in the second latch storage circuit, and then provided to the scan out signal SO through inverter circuits 212-213.

In the SET mode of programmable flip-flop circuit 400, signal SSB is asserted to a logic high state (1), and signal DETS is asserted to a logic low state (0). In the SET mode, pass gate circuits 221 and 223 are off, pass gate circuits 222 and 224 are on, and the output of inverter circuit 201 is decoupled from the input of inverter circuit 208. During SET mode, the data input path that generates signal D is coupled to the input of inverter circuit 207 and decoupled from the input of inverter circuit 208. Also, because signal DETS is 0 in SET mode, NAND gate circuit 404 continuously generates a logic high state (1) at its output, causing pass gate circuit 227 to remain off and pass gate circuit 228 to remain on.

In the SET mode of programmable flip-flop circuit 400, the value of the data input signal D is provided through inverter circuit 201, pass gate circuit 222, inverter circuit 207, and pass gate circuit 225 to the first latch storage circuit and then stored in the first latch storage circuit on each rising edge of clock signal CLK. Subsequently, the value of data signal D stored in the first latch storage circuit is provided to the second latch storage circuit (through inverter circuits 205-206, pass gate circuit 224, inverter circuit 208, and pass gate circuit 226), then stored in the second latch storage circuit on each falling edge of clock signal CLK, and then provided through pass gate circuit 228 and inverter circuit 216 to the output signal Q.

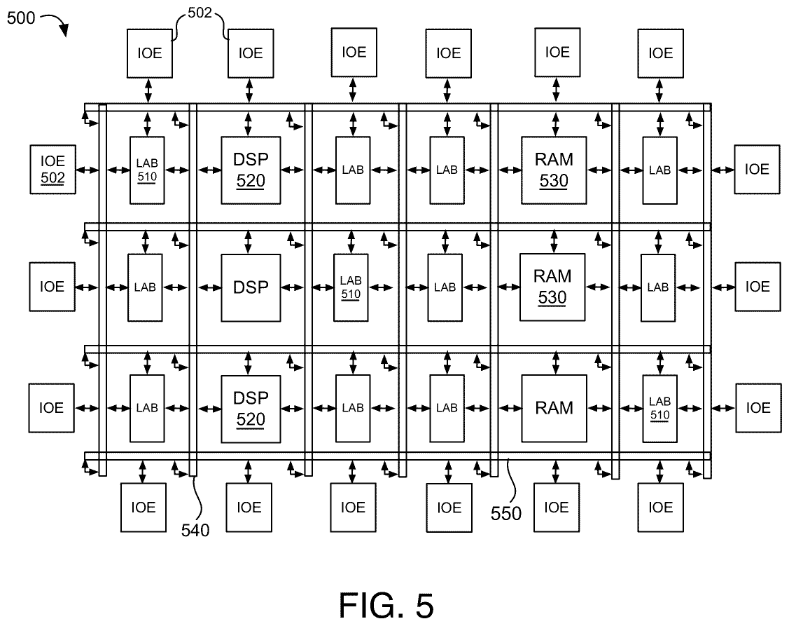

FIG. 5 illustrates an example of a configurable logic integrated circuit (IC) 500 that can include, for example, the circuitry disclosed herein with respect to any, some, or all of FIGS. 1, 2, and/or 4. As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals. The configurable logic IC shown in FIG. 5 can, for example, include programmable flip-flop circuits 200 and/or 400.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The programmable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

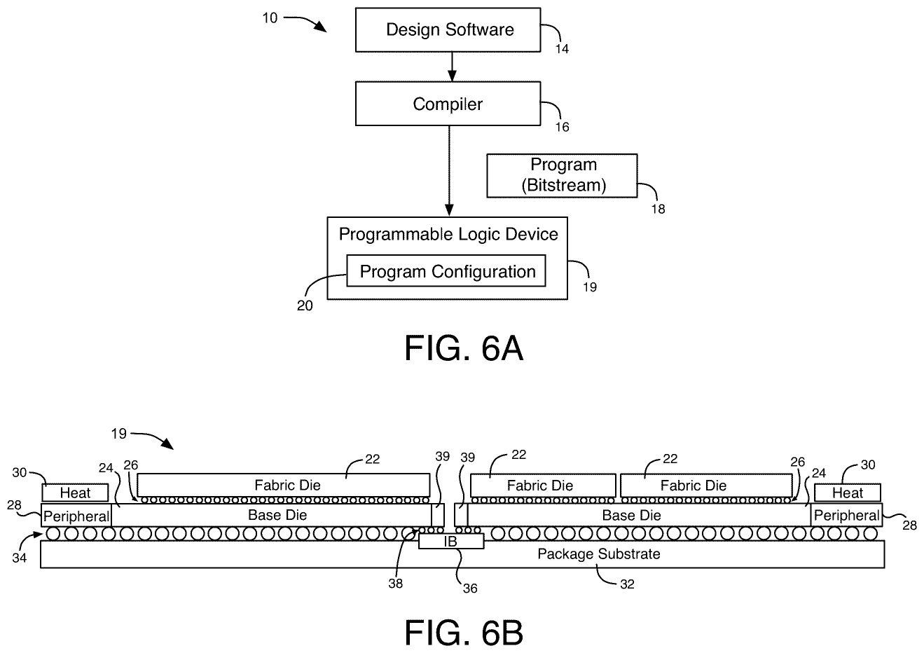

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

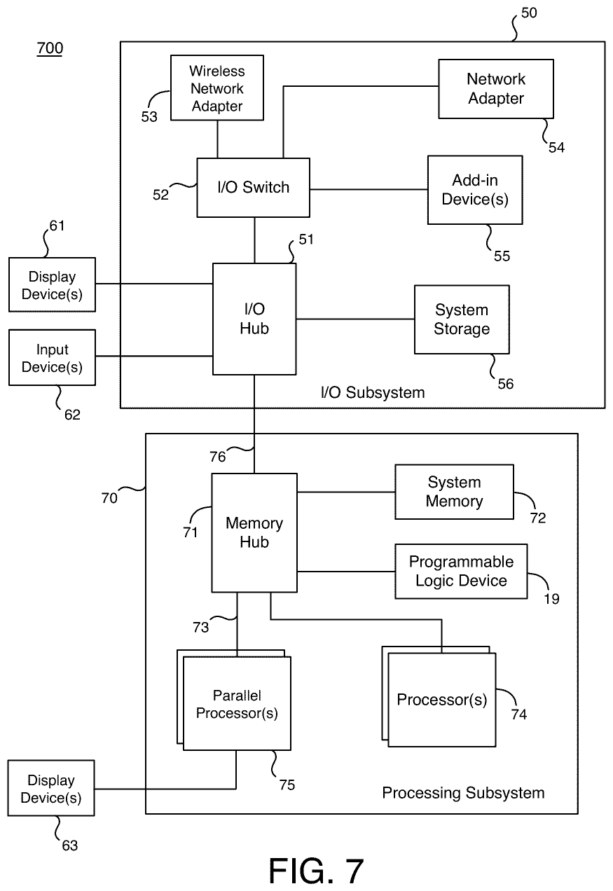

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is a flip-flop circuit comprising: first and second storage circuits, wherein the flip-flop circuit is configurable to store first values of a data signal in the first storage circuit in response to rising edges of a clock signal and to store second values of the data signal in the second storage circuit in response to falling edges of the clock signal during a double edge triggered mode, and wherein the flip-flop circuit is configurable to store third values of the data signal in the first storage circuit and to output the third values from the first storage circuit in response to the clock signal during a single edge triggered mode.

In Example 2, the flip-flop circuit of Example 1 can optionally include, wherein the flip-flop circuit is configurable to store fourth values of a scan in signal in the first and the second storage circuits in response to the clock signal and to output the fourth values in a scan out signal during a scan mode.

In Example 3, the flip-flop circuit of any one of Examples 1-2 can optionally include, wherein the flip-flop circuit is configurable to output the first values of the data signal from the first storage circuit through a first pass gate circuit to an output signal in response to the rising edges of the clock signal in the double edge triggered mode.

In Example 4, the flip-flop circuit of Example 3 can optionally include, wherein the flip-flop circuit is configurable to output the second values of the data signal from the second storage circuit through a second pass gate circuit to the output signal in response to the falling edges of the clock signal in the double edge triggered mode.

In Example 5, the flip-flop circuit of any one of Examples 1-4 can optionally include, wherein the flip-flop circuit is configurable to output the third values from the first storage circuit through a pass gate circuit in response to the clock signal during the single edge triggered mode.

In Example 6, the flip-flop circuit of any one of Examples 1-5 can optionally include, wherein the flip-flop circuit is configurable during a scan mode to store fourth values of a scan in signal in the first storage circuit in response to the rising edges of the clock signal, to provide the fourth values from the first storage circuit to the second storage circuit, and to store the fourth values in the second storage circuit in response to the falling edges of the clock signal.

In Example 7, the flip-flop circuit of any one of Examples 1-6 can optionally include, wherein the flip-flop circuit is configurable to output the first and the second values in an output signal during the double edge triggered mode at a first data rate, and wherein the flip-flop circuit is configurable to output the third values in the output signal during the single edge triggered mode at a second data rate that is half the first data rate.

In Example 8, the flip-flop circuit of any one of Examples 1-7 can optionally include, wherein the flip-flop circuit is configurable to store the third values of the data signal in the first and the second storage circuits and to output the third values from the first and the second storage circuits in response to the rising edges and the falling edges of the clock signal during the single edge triggered mode.

In Example 9, the flip-flop circuit of any one of Examples 1-8 can optionally include, wherein the first storage circuit comprises first cross-coupled inverter circuits, and wherein the second storage circuit comprises second cross-coupled inverter circuits.

Example 10 is a method for storing an input signal, the method comprising: storing first values of the input signal in first and second storage circuits in a programmable flip-flop circuit in response to a clock signal during a double edge triggered mode of the programmable flip-flop circuit; providing the first values from the first and the second storage circuits in an output signal in response to the clock signal during the double edge triggered mode; storing second values of the input signal in the first storage circuit in response to the clock signal during a single edge triggered mode of the programmable flip-flop circuit; and providing the second values from the first storage circuit in the output signal in response to the clock signal during the single edge triggered mode.

In Example 11, the method of Example 10 further comprises: storing third values of a scan in signal in the first and the second storage circuits in response to the clock signal during a scan mode of the programmable flip-flop circuit; and providing the third values from the second storage circuit in a scan out signal during the scan mode.

In Example 12, the method of any one of Examples 10-11 can optionally include, wherein storing the first values of the input signal in the first and the second storage circuits further comprises storing a first subset of the first values of the input signal in the first storage circuit in response to rising edges of the clock signal and storing a second subset of the first values of the input signal in the second storage circuit in response to falling edges of the clock signal during the double edge triggered mode.

In Example 13, the method of any one of Examples 10-12 can optionally include, wherein providing the first values from the first and the second storage circuits in the output signal further comprises providing a first subset of the first values from the first storage circuit to the output signal in response to rising edges of the clock signal and providing a second subset of the first values from the second storage circuit to the output signal in response to falling edges of the clock signal during the double edge triggered mode.

In Example 14, the method of any one of Examples 10-13 can optionally include, wherein storing the second values of the input signal in the first storage circuit further comprises storing the second values of the input signal in the first and the second storage circuits in response to the clock signal during the single edge triggered mode.

In Example 15, the method of Example 14 can optionally include, wherein providing the second values from the first storage circuit in the output signal further comprises providing the second values from the first and the second storage circuits in the output signal in response to the clock signal.

Example 16 is an integrated circuit comprising: a configurable storage circuit comprising a first latch circuit, a second latch circuit, a first pass gate circuit coupled to the first latch circuit, and a second pass gate circuit coupled to the second latch circuit, wherein the first and the second latch circuits store first values of a first input signal in response to a clock signal during a dual edge triggered mode, wherein the first values are provided from the first and the second latch circuits through the first and the second pass gate circuits to a first output signal in response to the clock signal, wherein the first and the second latch circuits store second values of a second input signal during a scan mode, and wherein the second values are provided from the second latch circuit to a second output signal during the scan mode.

In Example 17, the integrated circuit of Example 16 can optionally include, wherein the first latch circuit stores third values of the first input signal in response to the clock signal during a single edge triggered mode, and wherein the third values are provided from the first latch circuit through the first pass gate circuit to the first output signal during the single edge triggered mode.

In Example 18, the integrated circuit of any one of Examples 16-17 can optionally include, wherein the first latch circuit stores a first subset of the first values of the first input signal in response to rising edges of the clock signal during the dual edge triggered mode, and wherein the second latch circuit stores a second subset of the first values of the first input signal in response to falling edges of the clock signal during the dual edge triggered mode.

In Example 19, the integrated circuit of any one of Examples 16-18 can optionally include, wherein the first latch circuit stores the second values of the second input signal in response to rising edges of the clock signal during the scan mode, and wherein the second latch circuit receives the second values of the second input signal from the first latch circuit and stores the second values in response to falling edges of the clock signal during the scan mode.

In Example 20, the integrated circuit of any one of Examples 16-19 can optionally include, wherein the configurable storage circuit further comprises a third pass gate circuit coupled to the first latch circuit and a fourth pass gate circuit coupled to the second latch circuit, wherein the first latch circuit receives a first subset of the first values of the first input signal through the third pass gate circuit, and wherein the second latch circuit receives a second subset of the first values of the first input signal through the fourth pass gate circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A flip-flop circuit comprising:
first and second storage circuits, wherein the flip-flop circuit is configurable to store first values of a data signal in the first storage circuit in response to rising edges of a clock signal and to store second values of the data signal in the second storage circuit in response to falling edges of the clock signal during a double edge triggered mode, and wherein the flip-flop circuit is configurable to store third values of the data signal in the first storage circuit and to output the third values from the first storage circuit in response to the clock signal during a single edge triggered mode.

2. The flip-flop circuit of claim 1, wherein the flip-flop circuit is configurable to store fourth values of a scan in signal in the first and the second storage circuits in response to the clock signal and to output the fourth values in a scan out signal during a scan mode.

3. The flip-flop circuit of claim 1, wherein the flip-flop circuit is configurable to output the first values of the data signal from the first storage circuit through a first pass gate circuit to an output signal in response to the rising edges of the clock signal in the double edge triggered mode.

4. The flip-flop circuit of claim 3, wherein the flip-flop circuit is configurable to output the second values of the data signal from the second storage circuit through a second pass gate circuit to the output signal in response to the falling edges of the clock signal in the double edge triggered mode.

5. The flip-flop circuit of claim 1, wherein the flip-flop circuit is configurable to output the third values from the first storage circuit through a pass gate circuit in response to the clock signal during the single edge triggered mode.

6. The flip-flop circuit of claim 1, wherein the flip-flop circuit is configurable during a scan mode to store fourth values of a scan in signal in the first storage circuit in response to the rising edges of the clock signal, to provide the fourth values from the first storage circuit to the second storage circuit, and to store the fourth values in the second storage circuit in response to the falling edges of the clock signal.

7. The flip-flop circuit of claim 1, wherein the flip-flop circuit is configurable to output the first and the second values in an output signal during the double edge triggered mode at a first data rate, and wherein the flip-flop circuit is configurable to output the third values in the output signal during the single edge triggered mode at a second data rate that is half the first data rate.

8. The flip-flop circuit of claim 1, wherein the flip-flop circuit is configurable to store the third values of the data signal in the first and the second storage circuits and to output the third values from the first and the second storage circuits in response to the rising edges and the falling edges of the clock signal during the single edge triggered mode.

9. The flip-flop circuit of claim 1, wherein the first storage circuit comprises first cross-coupled inverter circuits, and wherein the second storage circuit comprises second cross-coupled inverter circuits.

10. A method for storing an input signal, the method comprising:
storing first values of the input signal in first and second storage circuits in a programmable flip-flop circuit in response to a clock signal during a double edge triggered mode of the programmable flip-flop circuit;
providing the first values from the first and the second storage circuits in an output signal in response to the clock signal during the double edge triggered mode;
storing second values of the input signal in the first storage circuit in response to the clock signal during a single edge triggered mode of the programmable flip-flop circuit; and
providing the second values from the first storage circuit in the output signal in response to the clock signal during the single edge triggered mode.

11. The method of claim 10 further comprising:
storing third values of a scan in signal in the first and the second storage circuits in response to the clock signal during a scan mode of the programmable flip-flop circuit; and
providing the third values from the second storage circuit in a scan out signal during the scan mode.

12. The method of claim 10, wherein storing the first values of the input signal in the first and the second storage circuits further comprises storing a first subset of the first values of the input signal in the first storage circuit in response to rising edges of the clock signal and storing a second subset of the first values of the input signal in the second storage circuit in response to falling edges of the clock signal during the double edge triggered mode.

13. The method of claim 10, wherein providing the first values from the first and the second storage circuits in the output signal further comprises providing a first subset of the first values from the first storage circuit to the output signal in response to rising edges of the clock signal and providing a second subset of the first values from the second storage circuit to the output signal in response to falling edges of the clock signal during the double edge triggered mode.

14. The method of claim 10, wherein storing the second values of the input signal in the first storage circuit further comprises storing the second values of the input signal in the first and the second storage circuits in response to the clock signal during the single edge triggered mode.

15. The method of claim 14, wherein providing the second values from the first storage circuit in the output signal further comprises providing the second values from the first and the second storage circuits in the output signal in response to the clock signal.

16. An integrated circuit comprising:
a configurable storage circuit comprising a first latch circuit, a second latch circuit, a first pass gate circuit coupled to the first latch circuit, and a second pass gate circuit coupled to the second latch circuit,
wherein the first and the second latch circuits store first values of a first input signal in response to a clock signal during a dual edge triggered mode, wherein the first values are provided from the first and the second latch circuits through the first and the second pass gate circuits to a first output signal in response to the clock signal,
wherein the first and the second latch circuits store second values of a second input signal during a scan mode, and wherein the second values are provided from the second latch circuit to a second output signal during the scan mode.

17. The integrated circuit of claim 16, wherein the first latch circuit stores third values of the first input signal in response to the clock signal during a single edge triggered mode, and wherein the third values are provided from the first latch circuit through the first pass gate circuit to the first output signal during the single edge triggered mode.

18. The integrated circuit of claim 16, wherein the first latch circuit stores a first subset of the first values of the first input signal in response to rising edges of the clock signal during the dual edge triggered mode, and wherein the second latch circuit stores a second subset of the first values of the first input signal in response to falling edges of the clock signal during the dual edge triggered mode.

19. The integrated circuit of claim 16, wherein the first latch circuit stores the second values of the second input signal in response to rising edges of the clock signal during the scan mode, and wherein the second latch circuit receives the second values of the second input signal from the first latch circuit and stores the second values in response to falling edges of the clock signal during the scan mode.

20. The integrated circuit of claim 16, wherein the configurable storage circuit further comprises a third pass gate circuit coupled to the first latch circuit and a fourth pass gate circuit coupled to the second latch circuit, wherein the first latch circuit receives a first subset of the first values of the first input signal through the third pass gate circuit, and wherein the second latch circuit receives a second subset of the first values of the first input signal through the fourth pass gate circuit.
